(19) United States
(12) Patent Application Publication
(10) Pub. No.: US 2026/0107591 A1
(43) Pub. Date: Apr. 16, 2026

(54) SEMICONDUCTOR PACKAGING STRUCTURE

(71) Applicant: TONG HSING ELECTRONIC INDUSTRIES, LTD., Taoyuan City (TW)

(72) Inventors: Tien-Hao Cheng, Taoyuan City (TW); Cheng-Chang Wu, Taoyuan City (TW); Li-Chun Hung, Taoyuan City (TW)

(73) Assignee: TONG HSING ELECTRONIC INDUSTRIES, LTD., Taoyuan City (TW)

(21) Appl. No.: 18/978,639

(22) Filed: Dec. 12, 2024

(30) Foreign Application Priority Data
Oct. 16, 2024 (TW) 113139431

(51) Int. Cl. H10F 39/00

(52) U.S. Cl. CPC H10F 39/804; H10F 39/811

(57) ABSTRACT

A semiconductor packaging structure includes a substrate, an image sensor chip, metal wires, a lid, a molding layer, and a ball grid array. The image sensor chip is on the substrate. The metal wires are electrically connected to the image sensor chip and upper contacts of the substrate. A lower surface of the lid is connected to a side surface thereof, and a lid angle between the lower surface and the side surface is greater than 90 degrees. The molding layer laterally encapsulates the substrate, the metal wires, the image sensor chip, and the lid to expose a portion of an upper surface of the image sensor chip. The molding layer, the lower surface, and the exposed portion of the image sensor chip together define an air cavity. The ball grid array includes solder balls, and each of the solder ball is electrically connected to lower contacts of the substrate.

### CROSS-REFERENCE TO RELATED APPLICATION

This non-provisional application claims priority under 35 U.S.C. § 119(a) to patent application Ser. No. 11/313,9431 filed in Taiwan, R.O.C. on Oct. 16, 2024, and the entire contents of which are hereby incorporated by reference.

### BACKGROUND

### Technical Field

The instant disclosure relates to a semiconductor packaging structure, and in particular to a semiconductor packaging structure of an image sensor chip.

### Related Art

Please refer to FIG. 1. FIG. 1 is a schematic cross-sectional view of a semiconductor packaging structure 1 known to the inventors. In FIG. 1, the semiconductor packaging structure 1 mainly includes a substrate 10, a ball grid array 11 (including solder balls 110), an image sensor chip 12, a lid 13, spacers 14, metal wires 16, and molding layers 17, 18. The spacers 14 usually need to be disposed at two sides of the image sensor chip 12, and the lid 13 is disposed on the two spacers 14, so that the image sensor chip 12, the two spacers 14 and the lid 13 together define an air cavity 15. The molding layers 17, 18 laterally encapsulate the two intermediates 14 and two sides of the lid 13. The arrangements of the substrate 10, the ball grid array 11 (and its solder balls 110), and the metal wires 16 can be referred to FIG. 1, which will not be described in detail herein.

### SUMMARY

However, in the semiconductor packaging structure 1 known to the inventors (as shown in FIG. 1), the lateral encapsulation of the molding layer 17 (or even the molding layer 18) will be limited by the arrangements of the spacers 14, thereby generating encapsulation defects. Therefore, the yield and reliability of the overall semiconductor packaging structure 1 would be affected.

Furthermore, in the semiconductor packaging structure 1 known to the inventors (as shown in FIG. 1), the volume of the air cavity 15 is relatively larger, so more air would be stored in the semiconductor packaging structure 1. However, the lid 13, the molding layers 17, 18, and the substrate 10 are all impermeable components; therefore, when the semiconductor packaging structure 1 subsequently undergoes other heat treatment processes (e.g., a reflow process), due to thermal expansion, the air in the air cavity 15 will result in a pressure difference between the inside and the outside of the air cavity 15. This pressure difference may lead to the failure of the adhesive surface between the lid 13 and the molding layers 17, 18, thereby affecting the yield and reliability of the overall semiconductor packaging structure 1.

In view of this, a semiconductor packaging structure according to some embodiments of the instant disclosure is provided. The semiconductor packaging structure comprises a substrate, an image sensor chip, a plurality of metal wires, a lid, a first molding layer, and a ball grid array. The substrate has an upper surface, a lower surface, and a trace between the upper surface and the lower surface. The upper surface of the substrate has a plurality of upper contacts, the lower surface of the substrate has a plurality of lower contacts, and the upper contacts are electrically connected to the lower contacts through the trace. The image sensor chip is on the upper surface of the substrate. One end of each of the metal wires is electrically connected to the image sensor chip, and the other end of each of the metal wires is electrically connected to the upper contacts of the substrate. The lid has a lower surface and a first side surface, where the lower surface of the lid is connected to the first side surface of the lid, and a first lid angle between the lower surface of the lid and the first side surface of the lid is greater than 90 degrees. The first molding layer laterally encapsulates the substrate, the metal wires, the image sensor chip, and the lid to expose a portion of the upper surface of the image sensor chip. The first molding layer, the lower surface of the lid, and the exposed portion of an upper surface of the image sensor chip together define an air cavity. The ball grid array comprises a plurality of solder balls, and each of the solder balls is individually electrically connected to each of the lower contacts of the substrate.

In some embodiments, the lid further has a second side surface. The second side surface of the lid is connected to the first side surface of the lid, and a second lid angle between the lower surface of the lid and the second side surface of the lid is less than or equal to the first lid angle.

### BRIEF DESCRIPTION OF THE DRAWINGS

The instant disclosure will be more fully understood when the detailed description given herein below. It should be noted that, in accordance with standard practice in the industry, various features are not drawn to scale and are for illustration only. Practically, the dimensions of the various features may be arbitrarily increased or decreased for clarity of description.

FIG. 1 is a schematic cross-sectional view of a semiconductor packaging structure known to the inventors;

FIG. 2 is a schematic cross-sectional view of a semiconductor packaging structure according to a first embodiment;

FIG. 3A to FIG. 3F are schematic cross-sectional views of semi-finished products of the semiconductor packaging structure shown in FIG. 2;

FIG. 4A is a schematic cross-sectional view of a semi-finished product of a cover according to some embodiments;

FIG. 4B and FIG. 4C are schematic cross-sectional views of a cover according to some embodiments;

FIG. 5A to FIG. 5C are schematic cross-sectional views of a semi-finished product of a lid according to some embodiments;

FIG. 5D is a schematic cross-sectional view of a lid according to some embodiments;

FIG. 6 is a schematic cross-sectional view of a semiconductor packaging structure according to a second embodiment; and

FIG. 7 is a schematic cross-sectional view of a lid according to some embodiments.

### DETAILED DESCRIPTION

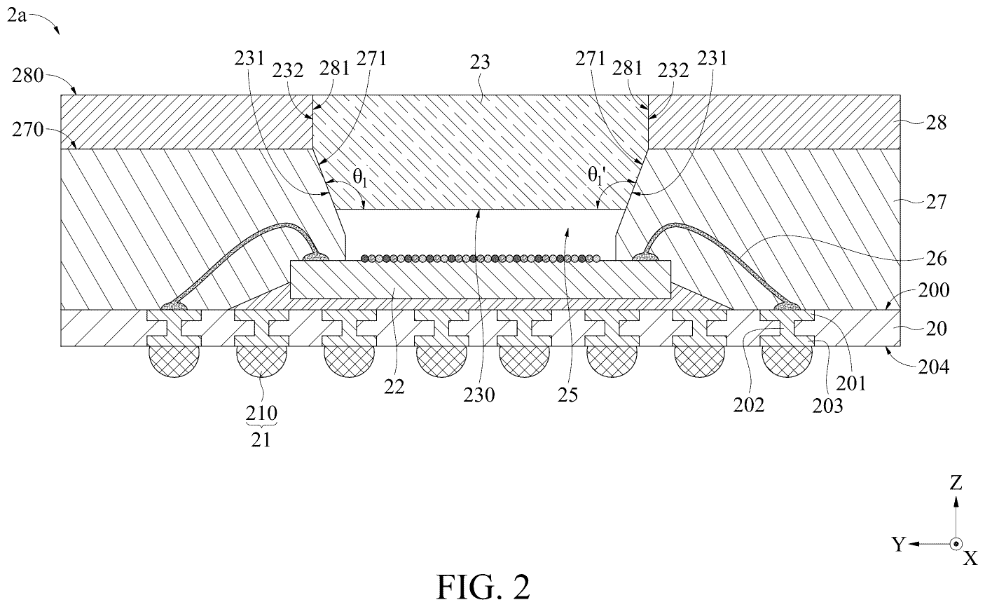

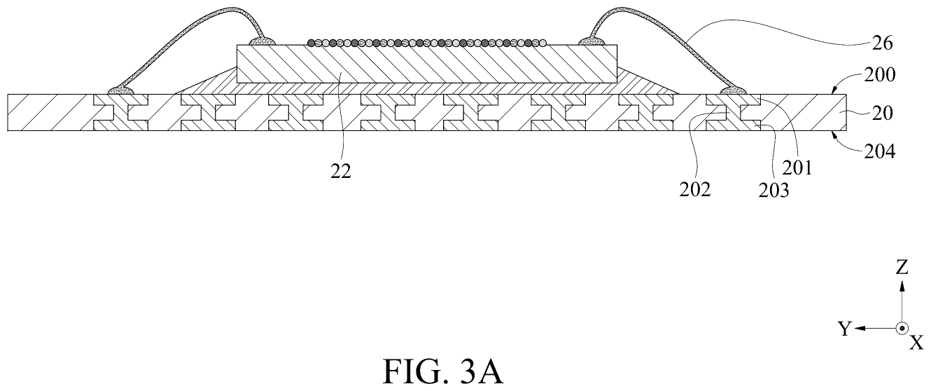

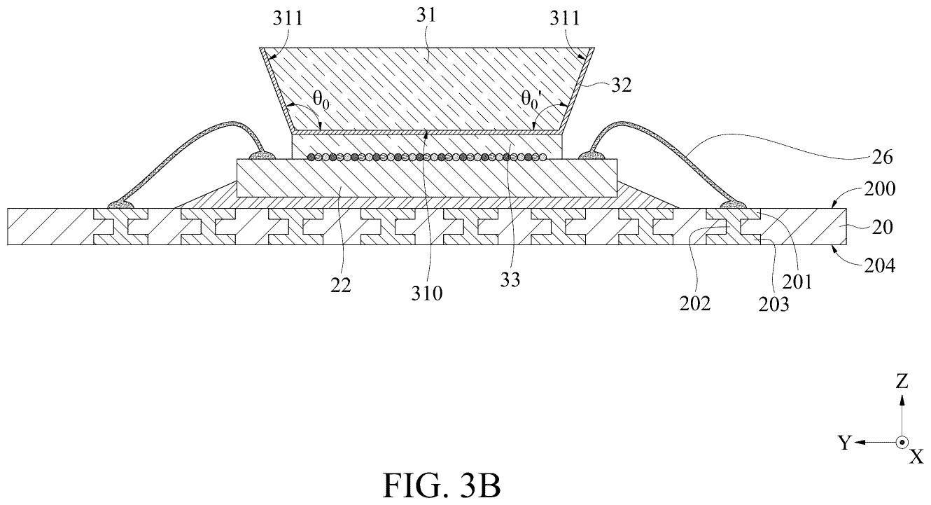

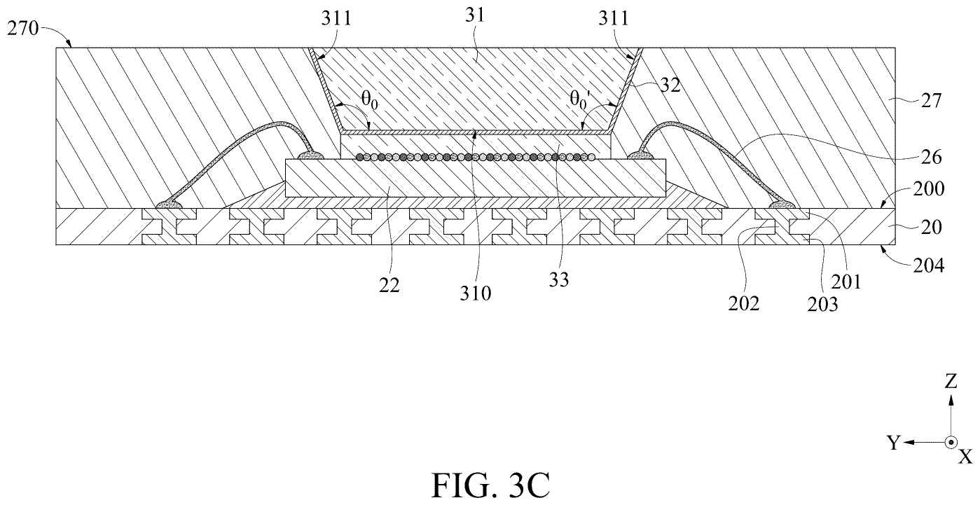

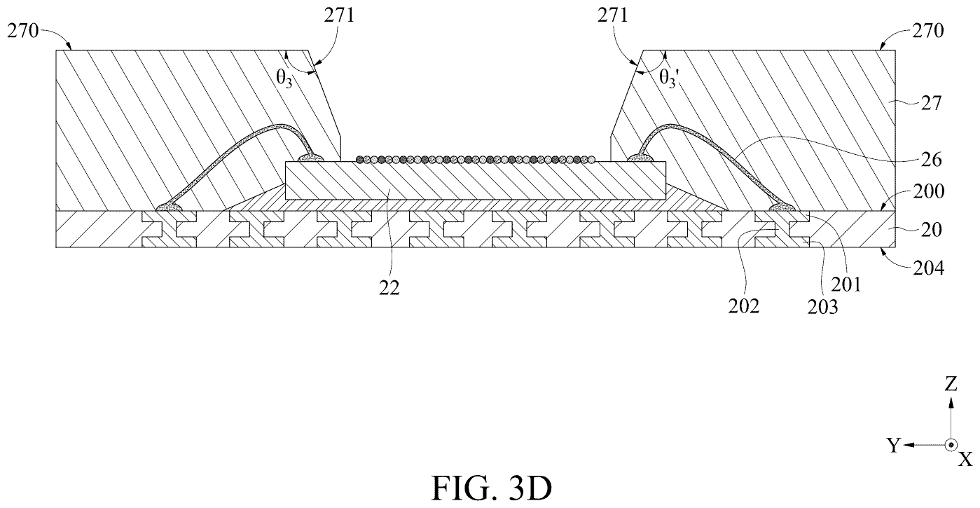

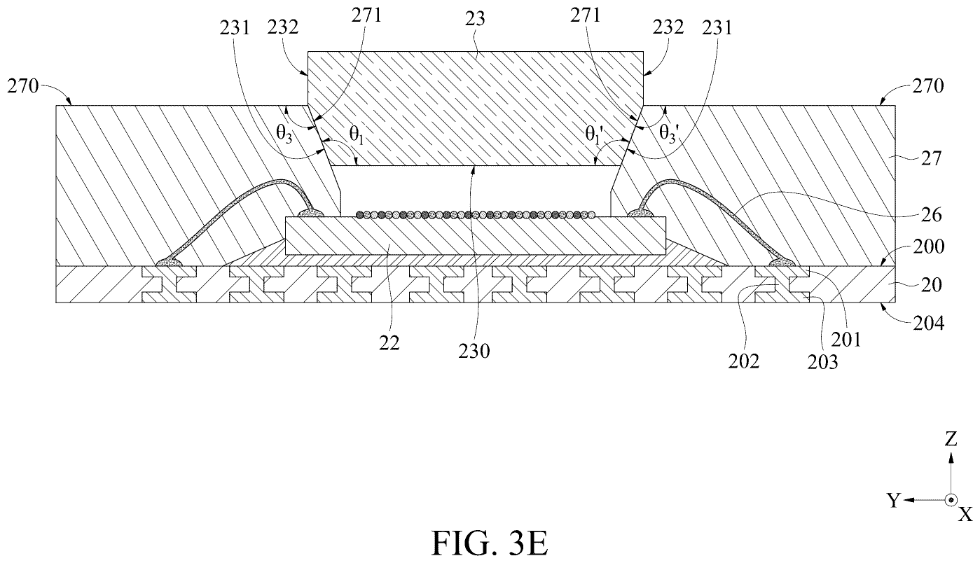

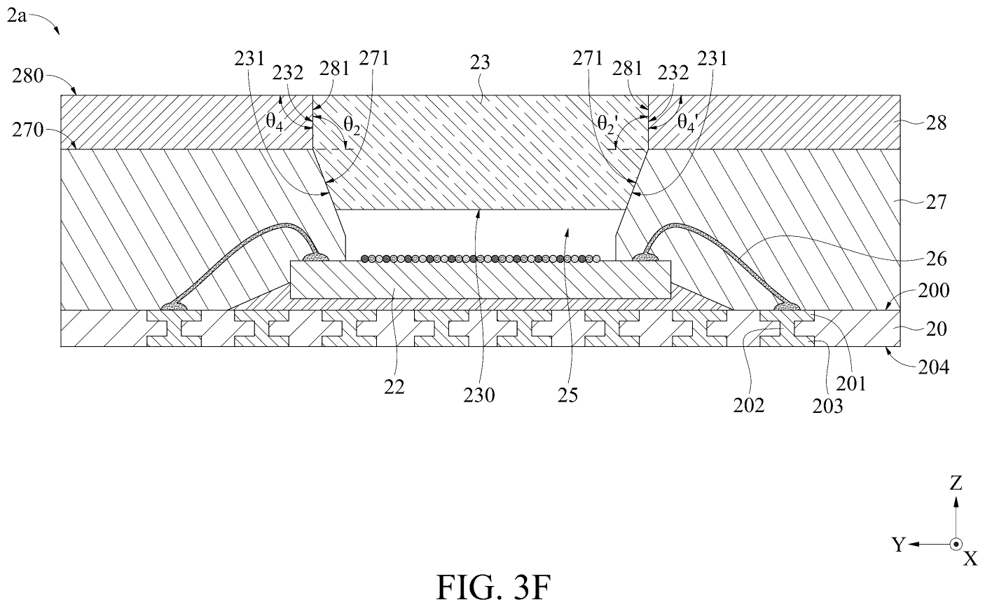

Please refer to FIG. 2 and FIG. 3E. FIG. 2 is a schematic cross-sectional view of a semiconductor packaging structure 2a according to a first embodiment; and FIG. 3E is a schematic cross-sectional view of a semi-finished product of the semiconductor packaging structure 2a shown in FIG. 2. In FIG. 2, a semiconductor packaging structure 2a comprises a substrate 20, an image sensor chip 22, a plurality of metal wires 26, a lid 23, a first molding layer 27, and a ball grid array 21. In a cross-section (e.g., the YZ plane shown in FIG. 2 and FIG. 3E), the substrate 20 has an upper surface 200, a lower surface 204, and a trace 202 between the upper surface 200 and the lower surface 204. The upper surface 200 of the substrate 20 has a plurality of upper contacts 201, the lower surface 204 of the substrate 20 has a plurality of lower contacts 203, and each of the upper contacts 201 is individually electrically connected to at least one of the lower contacts 203 through the trace 202. The image sensor chip 22 is on the upper surface 200 of the substrate 20. One end of each of the metal wires 26 is electrically connected to the image sensor chip 22, and the other end of each of the metal wires 26 is electrically connected to at least one of the upper contacts 201. The lid 23 has an upper surface (not labeled), a lower surface 230, and first side surfaces 231. The lower surface 230 of the lid 23 is connected to the first side surfaces 231 of the lid 23, and the lower surface 230 of the lid 23 and the first side surfaces 231 define first lid angles θ₁, θ₁′ (shown in FIG. 2 or FIG. 3E). The first lid angles θ₁, θ₁′ refer to angles formed between the lower surface 230 of the lid 23 and the first side surfaces 231 at the two sides of the lid 23, respectively. The first lid angles θ₁, θ₁′ may be different from each other but the first lid angles θ₁, θ₁′ are still greater than 90 degrees. The first molding layer 27 laterally encapsulates the substrate 20, the metal wires 26, the image sensor chip 22, and the lid 23 to expose a portion of the upper surface of the image sensor chip 22 (not labeled). The first molding layer 27, the lower surface 230 of the lid 23, and the exposed portion of an upper surface of the image sensor chip 22 together define an air cavity 25. The ball grid array 21 comprises a plurality of solder balls 210, and each of the solder balls 210 is individually electrically connected to at least one of the lower contacts 203.

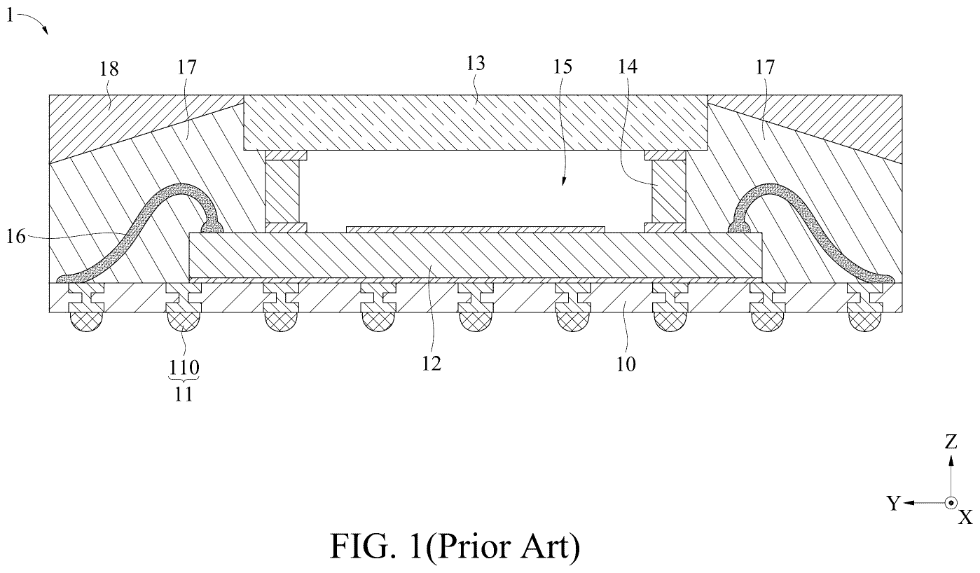

Accordingly, in some embodiments, through setting the width of the upper surface of the lid 23 to be greater than that of the lower surface 230 of the lid 23 (i.e., the lid 23 is set to be wider at the top and narrower at the bottom), the lid 23 may be clamped on the top of the image sensor chip 22 and does not need to dispose the spacers 14 shown in FIG. 1, thereby avoiding generating encapsulation defects between the molding layer 17 (or even the molding layer 18) and the spacers 14 (and/or the lid 13 known to the inventors). Meanwhile, in some embodiments, the height of the air cavity 15 (i.e., the size of the air cavity 15 along the Z direction shown in FIG. 1) may be greatly reduced to the height of the air cavity 25 (i.e., the size of the air cavity 25 along the Z direction shown in FIG. 2); therefore, the failure of the adhesive surface between the lid 13 and the molding layers 17, 18 known to the inventors, resulted from this pressure difference due to the sequential processes, can be avoided. Hence, the yield and reliability of the overall semiconductor packaging structure 1 can be prevented from being affected, and thus a better (or even a more enhanced) yield and reliability can be maintained (or achieved).

Moreover, since the lid 13 shown in FIG. 1 can be used to transmit light, and once the light enters the air cavity 15, the light will be affected by the reflection of the surroundings of the air cavity 15 (e.g., the lower surface of the lid 13 (not labeled) and the spacers 14 at the two sides of the air cavity 15) and thus the reflected light will be transmitted back and forth in the air cavity 15, thereby causing unnecessary interferences to the image sensor chip 12. For example, the light transmitted in the air cavity 15 can be further reflected or transmitted to the spacers 14 and/or the lid 13 and then cause unnecessary flare phenomenon.

On the contrary, in some embodiments, through setting the lid 23 to be wider at the top and narrower at the bottom shown in FIG. 2, the light transmission path in the lid 23 can be changed due to the reflection of the first side surfaces 231, and thus the probability of the light transmitting to the air cavity 25 may be reduced, thereby avoiding unnecessary interferences caused by the light transmitting back and forth in the air cavity 25. Furthermore, in some embodiments, even if the light further transmits into the air cavity 25, since there is no need to provide the spacers 14 in the semiconductor packaging structure 2a shown in FIG. 1, the light at the two sides of the air cavity 25 will not be reflected or transmit to the spacers 14 to cause unnecessary flare phenomenon. At the same time, because the light at the two sides of the air cavity 25 will no longer penetrate to or transmit in the first molding layer 27, the radiation of light on the two sides of the air cavity 25 will be limited within the air cavity 25, so that the unnecessary flare phenomenon can be avoided more effectively.

In addition, in some embodiments, through setting the lid 23 to be wider at the top and narrower at the bottom shown in FIG. 2, there is no need to provide a light shielding layer on the lower surface 230 of the lid 23 as known to the inventors, which can not only save the process time and costs required to set up the light shielding layer but also avoid unnecessary flare phenomenon more effectively. For example, the material of the light shielding layer may be photoresist, black ink (or black mask) or other black glue materials.

Please refer to FIG. 2 and FIG. 3F. FIG. 3F are schematic cross-sectional views of a semi-finished product of the semiconductor packaging structure 2a shown in FIG. 2. In a cross-section (e.g., the YZ plane shown in FIG. 2 and FIG. 3F), the lid 23 further has second side surfaces 232. The second side surfaces 232 of the lid 23 are respectively connected to the first side surfaces 231 of the lid 23, and the lower surface 230 of the lid 23 and the second side surfaces 232 of the lid 23 define second lid angles θ₂, θ₂′ (as shown in FIG. 3F). The second lid angles θ₂, θ₂′ refer to angles formed between the lower surface 230 of the lid 23 (e.g., a virtual plane or a virtual line parallel to the lower surface 230) and the second side surfaces 232 at the two sides of the lid 23, respectively. The second lid angles θ₂, θ₂′ may be different from each other but the second lid angles θ₂, θ₂′ are still less than or equal to the corresponding first lid angles θ₁, θ₁′ at the two sides of the lid 23 (as shown in FIG. 2); for example, the second lid angle θ₂ is less than or equal to the corresponding first lid angle θ₁ at the same side of the lid 23, and the second lid angle θ₂′ is less than or equal to the corresponding first lid angle θ₁′ at the same other side of the lid 23. For another example, both of the second lid angles θ₂, θ₂′ are about 90 degrees (shown in FIG. 2 and FIG. 3F), and both are less than the corresponding first lid angles θ₁, θ₁′ (shown in FIG. 2). Accordingly, in some embodiments, through setting the first side surface 231 and the second side surface 232 at each of the two sides of the lid 23 as non-coplanar, the light transmission path in the lid 23 can be changed by the reflection of the first side surfaces 231 and the second side surfaces 232 of the lid 23, and thus the probability of the light transmitting to the air cavity 25 can be reduced, thereby avoiding unnecessary interferences caused by the light transmitting back and forth in the air cavity 25 (e.g., flare phenomenon).

Please refer to FIG. 2 and FIG. 3F. According to some embodiments, the semiconductor packaging structure 2a further comprises a second molding layer 28, and the second molding layer 28 is located on the first molding layer 27 and laterally encapsulates the lid 23. For example, in FIG. 2, the first molding layer 27 laterally encapsulates the first side surfaces 231 of the lid 23, and the second molding layer 28 laterally encapsulates the second side surfaces 232 of the lid 23. Therefore, in some embodiments, through the arrangements of the first side surfaces 231 and the second side surfaces 232 of the lid 23, the light transmission path in the lid 23 can be changed by the reflection of the first side surfaces 231 and the second side surfaces 232 of the lid 23, and thus the probability of the light transmitting to the air cavity 25 can be reduced, thereby avoiding unnecessary interferences caused by the light transmitting back and forth in the air cavity 25 (e.g., flare phenomenon).

The specific implementations and manufacturing processes of the semiconductor packaging structure 2a are exemplarily described as below through FIG. 2 and FIG. 3A to FIG. 3F.

Please refer to FIG. 3A. FIG. 3A are schematic cross-sectional views of a semi-finished product of the semiconductor packaging structure 2a shown in FIG. 2. The substrate 20 has an upper surface 200 and a lower surface 204 opposite to the upper surface 200. The upper surface 200 is provided with a plurality of upper contacts 201, and the lower surface 204 is provided with a plurality of lower contacts 203. The substrate 20 also has a plurality of traces 202 to selectively have a portion of the upper contacts 201 electrically connected to a portion of the lower contacts 203. In other words, each of the upper contacts 201 may be electrically connected to one or more of the lower contacts 203 through the trace(s) 202, and each of the lower contacts 203 may be electrically connected to one or more of the upper contacts 201 through the trace(s) 202. Hence, a person of ordinary skill in the art can fully understand that the arrangements of the upper contacts 201, the traces 202, and the lower contacts 203 of the instant disclosure are not limited to the arrangements exemplarily shown in the drawings (e.g., FIG. 3A and FIG. 2) and can be modified based on various demands, which are thus all included in the scope of the instant disclosure. In some embodiments, the substrate 20 is a laminated material composed of multiple layers of glass fiber composite materials. In some embodiments, the substrate 20 is a ceramic substrate selected from the following materials: silicon nitride (Si₃N₄), aluminum oxide (Al₂O₃), aluminum nitride (AlN), zirconium oxide (ZrO₂), zirconium oxide toughened alumina (ZTA), and beryllium oxide (BeO).

Please refer to FIG. 3A. The image sensor chip 22 has an active surface (e.g., the upper surface of the image sensor chip 22 shown in FIG. 3A) and a back surface (e.g., the lower surface of the image sensor chip 22 shown in FIG. 3A). The image sensor chip 22 with its active surface facing upwards is fixed on the upper surface 200 of the substrate 20 through a die-bonding adhesive (e.g., the die-bonding adhesive between the lower surface of the image sensor chip 22 and the upper surface 200 of the substrate 20 shown in FIG. 3A). The active surface of the image sensor chip 22 may comprise an image sensing area (e.g., the middle portion of the upper surface of the image sensor chip 22 shown in FIG. 3A) and a plurality of solder pads around the image sensing area (e.g., the two side portions of the upper surface of the image sensor chip 22 shown in FIG. 3A). The image sensor chip 22 may be electrically connected to an external circuit through the solder pads. In some embodiments, the solder pads are located at two opposite sides of the image sensing area (e.g., the two sides of the upper surface of the image sensor chip 22 shown in FIG. 3A).

Please still refer to FIG. 3A, the metal wires 26 are electrically connected to the image sensor chip 22 and the upper surface 200 of the substrate 20 in a manner of wire bonding. For example, one end of each of the metal wires 26 is bonded with at least one of the solder pads of the image sensor chip 22, and the other end of each of the metal wires 26 is bonded with at least one of the upper contacts 201 of the substrate 20.

Please refer to FIG. 3B. FIG. 3B are schematic cross-sectional views of a semi-finished product of the semiconductor packaging structure 2a shown in FIG. 2. In a cross-section (e.g., the YZ plane shown in FIG. 3B), the cover 31 has an upper surface (not labeled), a lower surface 310, and side surfaces 311. The lower surface 310 of the cover 31 is connected to the side surfaces 311 of the cover 31. The lower surface 310 of the cover 31 and the side surfaces 311 of the cover 31 define cover angles θ₀, θ₀′, and the cover angles θ₀, θ₀′ between the lower surface 310 of the cover 31 and the side surfaces 311 of the cover 31 may be different from each other but the cover angles θ₀, θ₀′ are still greater than 90 degrees. In some embodiments, the cover angle θ₀ (shown in FIG. 3B) is arranged corresponding to the first lid angle θ₁ (shown in FIG. 2), while the cover angle θ₀′ (shown in FIG. 3B) is arranged corresponding to the first lid angle θ₁′ (shown in FIG. 2), so that the two sides of the lid 23 can be matched and clamped on the first molding layer 27 (shown in FIG. 2). For example, the cover angle θ₀ is equal to or slightly greater than the first lid angle θ₁, while the cover angle θ₀′ is equal to or slightly greater than the first lid angle θ₁′. In some embodiments, the material of the cover 31 is glass, and its transmittance to visible light is greater than 90%. The cover 31 can be obtained, for example, through the manufacturing method described as below, which will be described in detail later.

Please refer to FIG. 3B, the cover 31 is fixed on the active surface of the image sensor chip 22 (e.g., the image sensing area of the image sensor chip 22) through a second colloid 33. For example, the second colloid 33 is coated between the lower surface 310 of the cover 31 and the active surface of the image sensor chip 22. In some embodiments, the material of the second colloid 33 is water-soluble glue, which can be removed by water or various aqueous solutions. In other embodiments, the second colloid 33 is double-sided tape, foam tape, or a combination thereof, which can be removed by organic solvents or other physical means (e.g., peeling off). The thickness of the second colloid 33 can be adjusted according to various demands, which is not limited herein. Accordingly, through the arrangements of the second colloid 33, the cover 31 can be fixed on the image sensor chip 22, and the cover 31 and the image sensor chip 22 can also be protected from damage; in addition, in the subsequent processes, by removing the second colloid 33, the cover 31 can be quickly separated from the image sensor chip 22, thereby reducing the process time and costs.

Please still refer to FIG. 3B. In some embodiments, the cover 31 is further coated with a first colloid 32. For example, the first colloid 32 is coated on the lower surface 310 of the cover 31 and the side surfaces 311 of the cover 31, so that the cover 31 coated with the first colloid 32 can be fixed on the active surface of the image sensor chip 22 through the second colloid 33. In some embodiments, the material of the first colloid 32 is polyimide (PI), which can be removed by organic solvents. In other embodiments, the material of the first colloid 32 is water-soluble glue, which can be removed by water or various aqueous solutions. In other embodiments, the first colloid 32 is double-sided tape, foam tape, or a combination thereof, which can be removed by organic solvents or other physical means (e.g., peeling off). In some embodiments, the material of the first colloid 32 coated on the lower surface 310 of the cover 31 is different from the material of the first colloid 32 coated on the side surfaces 311 of the cover 31. Moreover, the first colloid 32 and the second colloid 33 may be made of the same or different materials, which is not limited herein; for example, both of the first colloid 32 and the second colloid 33 are water-soluble glues; or for another example, the first colloid 32 is polyimide while the second colloid 33 is a water-soluble glue. The thickness of the first colloid 32 can be adjusted according to various demands, which is not limited herein. Accordingly, through the arrangements of the first colloid 32, the cover 31 can be fixed on the image sensor chip 22 and the first molding layer 27 (shown in FIG. 3C, which will be described later), and the cover 31 can also be protected from damage; in addition, in the subsequent processes, by removing the first colloid 32, the cover 31 can be quickly separated from the image sensor chip 22 (or the second colloid 33) and the first molding layer 27, thereby reducing the process time and costs.

Please refer to FIG. 3C. FIG. 3C are schematic cross-sectional views of a semi-finished product of the semiconductor packaging structure 2a shown in FIG. 2. In FIG. 3C, the first molding layer 27 laterally encapsulates the substrate 20, the metal wires 26, the image sensor chip 22, the lid 23, the die-bonding adhesive, the first colloid 32, and the second colloid 33. In addition, the first molding layer 27 is conformally encapsulated with the surface profiles of the two sides of the cover 31, the two sides of the first colloid 32, and the two sides of the second colloid 33, so that the surface profiles of the first molding layer 27 match the surface profiles of the two sides of the cover 31, the two sides of the first colloid 32, and the two sides of the second colloid 33. For example, the material of the first molding layer 27 is a material with a lower melting point or glass transition temperature (e.g., lower than the temperature that will damage the image sensor chip 22), so that the first molding layer 27 can still maintain a liquid gel state with fluidity during filling, and thus for example, by dispensing, the surface profiles of the first molding layer 27 can conform with the surface profiles of the elements to be encapsulated (e.g., the cover 31, the first colloid 32, and the second colloid 33) as much as possible. In some embodiments, the material of the first molding layer 27 is a material with low light transmittance in the visible light range, such as a material containing epoxy resin.

Please refer to FIG. 3C and FIG. 3D. FIG. 3D are schematic cross-sectional views of a semi-finished product of the semiconductor packaging structure 2a shown in FIG. 2. In some embodiments, the surface profile of the cured first molding layer 27 matches the surface profiles of the two sides of the cover 31, the two sides of the first colloid 32, and the two sides of the second colloid 33. In some embodiments, in a cross-section (e.g., the YZ plane shown in FIG. 3D), the cured first molding layer 27 has an upper surface 270, a lower surface (not labeled), and first side surfaces 271. The upper surface 270 of the first molding layer 27 is connected to the first side surfaces 271 of the first molding layer 27. The upper surface 270 of the first molding layer 27 and the first side surfaces 271 of the first molding layer 27 define first molding angles θ₃, θ₃′. The first molding angles θ₃, θ₃′ refer to angles formed between the upper surface 270 of the first molding layer 27 and the first side surfaces 271 at the two sides of the first molding layer 27, respectively. The first molding angles θ₃, θ₃′ may be different from each other but the first molding angles θ₃, θ₃′ are still greater than 90 degrees. In some embodiments, the first molding angle θ₃ (shown in FIG. 3D) is arranged corresponding to the cover angle θ₀ (shown in FIG. 3C), while the first molding angle θ₃′ (shown in FIG. 3D) is arranged corresponding to the cover angle θ₀′ (shown in FIG. 3C), so that the two sides of the cover 31 (shown in FIG. 2 or FIG. 3E) can be matched and clamped on the first molding layer 27. For example, the cover angle θ₀ is equal to or slightly greater than the first molding angle θ₃, while the cover angle θ₀′ is equal to or slightly greater than the first molding angle θ₃′.

For example, the first molding angle θ₃ of the cured first molding layer 27 (shown in FIG. 3D) is equal to or slightly less than the cover angle θ₀ (shown in FIG. 3C), and the first molding angle θ₃′ of the cured first molding layer 27 (shown in FIG. 3D) is equal to or slightly less than the cover angle θ₀′ (shown in FIG. 3C). Accordingly, in FIG. 3D, when a portion of the upper surface of the image sensor chip 22 is exposed (e.g., the active surface of the image sensor chip 22 is exposed) after the cover 31, the first colloid 32, and the second colloid 33 shown in FIG. 3C are further removed, the obtained surface profiles of the first side surfaces 271 as shown in FIG. 3D may be substantially the same as the surface profiles of the side surfaces 311 of the cover 31.

Please refer to FIG. 3C and FIG. 3D. In some embodiments, the upper surface 270 of the cured first molding layer 27 is a horizontal plane and parallel to the upper surface 200 of the substrate 20. In some embodiments, the upper surface 270 of the cured first molding layer 27 is an inclined plane. For example, the thickness of the first molding layer 27 (i.e., the size along the Z direction in FIG. 3D) decreases in the direction away from the lid 23; that is, in such embodiments, the upper surface 270 of the cured first molding layer 27 may be arranged as the upper surface of the first molding layer 17 shown in FIG. 1. In some embodiments, the upper surface 270 of the cured first molding layer 27 and the upper surface of the cover 31 are arranged as coplanar (as shown in FIG. 3C); for example, the first molding layer 27 is thinned by chemical mechanical polishing until the upper surface of the cover 31 is exposed with the upper surface 270 of the first molding layer 27.

Please refer to FIG. 3E. After the cover 31 shown in FIG. 3C is removed, the lid 23 is clamped on the first molding layer 27 and can substantially correspond to the position of the cover 31 (shown in FIG. 3C), so that the first molding layer 27, the lower surface 230 of the lid 23, and a portion of the exposed image sensor chip 22 (e.g., the exposed image sensing area on the active surface of the image sensor chip 22) together define the air cavity 25. The lid 23 can be obtained, for example, through the manufacturing method described below, which will be described in detail later. In some embodiments, the air cavity 25 is a closed space.

Please refer to FIG. 3E. In some embodiments, the surface profiles of the lid 23 clamped on the first molding layer 27 (e.g., the surface profile of the first side surfaces 231 of the lid 23) match the surface profiles of the first side surfaces 271 of the first molding layer 27. For example, the first lid angle θ₁ of the first molding layer 27 is equal to or slightly greater than the first molding angle θ₃, while the first lid angle θ₁′ of the first molding layer 27 is equal to or slightly greater than the first molding angle θ₃′. Accordingly, in FIG. 3E, when the lid 23 is clamped on the first molding layer 27 so that the lid 23, the first molding layer 27, and a portion of the exposed image sensor chip 22 (e.g., the image sensing area on the active surface of the image sensor chip 22 is exposed) together define the air cavity 25, the obtained surface profile of the first side surface 271 of the first molding layer 27 may be substantially the same as the surface profiles of the lid 23 (e.g., the surface profiles of the first side surfaces 231 of the lid 23).

In some embodiments, since the lid 23 shown in FIG. 3E has been arranged, there is no need to further arrange the spacers 14 shown in FIG. 1. Therefore, encapsulation defects can be prevented from being generated between the spacers 14 and the molding layer 17 (or even the molding layer 18) shown in FIG. 1, thereby avoiding affecting the yield and reliability of the overall semiconductor packaging structure 1.

In addition, in some embodiments, since the lid 23 has been arranged, there is no need to further arrange the spacers 14 as shown in FIG. 1, and thus it is no more limited by the spacers 14 and the manufacturing process thereof; therefore, the volume of the air cavity 25 shown in FIG. 3E can be reduced as much as possible. Accordingly, in some embodiments, even though the semiconductor packaging structure 2a further undergoes other heat treatment processes, since the air in the air cavity 25 has been greatly reduced, the failure of the adhesive surface between the lid 23 and the molding layer 27 (or even the molding layer 28, which will be described later) shown in FIG. 3F can be avoided. Hence, a maintained (or even more enhanced) yield and reliability of the overall semiconductor packaging structure 2a can be provided.

Please refer to FIG. 3E and FIG. 3F. In some embodiments, in a cross-section (e.g., the YZ plane shown in FIG. 3E and FIG. 3F), the lid 23 further has second side surfaces 232. The second side surfaces 232 of the lid 23 are respectively connected to the first side surfaces 231 of the lid 23, and the lower surface 230 of the lid 23 (e.g., a virtual plane or a virtual line parallel to the lower surface 230) and the second side surfaces 232 of the lid 23 define second lid angles θ₂, θ₂′ (shown in FIG. 3F). The specific embodiments of the second side surfaces 232 of the lid 23 and the second lid angles θ₂, θ₂′ can be referred to the aforementioned embodiments, which will not be further described in detail herein. The lid 23 as well as the first side surfaces 271 of the first molding layer 27 and the second side surfaces 280 of the second molding layer 28 can be obtained, for example, through the manufacturing method described as below, which will be described in detail later. In some embodiments, the upper surface of the lid 23 is higher than the upper surface 270 of the first molding layer 27. In some embodiments, as shown in FIG. 3E, the position level of the upper surface 270 of the first molding layer 27 is at the same position level where the first side surfaces 231 of the lid 23 is connected to the second side surfaces 232 thereof, so that the second side surfaces 232 of the lid 23 are exposed.

Please refer to FIG. 3F. In some embodiments, the second molding layer 28 is located on the first molding layer 27 and laterally encapsulates the lid 23 and the first molding layer 27. Moreover, the second molding layer 28 is conformally encapsulated with the surface profiles of the two sides of the lid 23 (e.g., the surface profiles of the second side surfaces 232 of the lid 23), so that the surface profiles of the second molding layer 28 match the surface profiles of the two sides of the lid 23. For example, the material of the second molding layer 28 is a material with a lower melting point or glass transition temperature (e.g., lower than the temperature that will cause the first molding layer 27 to melt or deteriorate), so that the second molding layer 28 can still maintain a liquid gel state with fluidity during encapsulating the first molding layer 27, and thus the surface profiles of the second molding layer 28 after cured can conform with the surface profiles of the elements to be encapsulated (e.g., the lid 23 (e.g., the second side surfaces 232 of the lid 23) and the first molding layer 27). In some embodiments, the material of the second molding layer 28 is a material with low light transmittance in the visible light range, such as a material containing a thermal curing encapsulant.

In some embodiments, the surface profiles of the cured second molding layer 28 match the surface profiles of the two sides of the lid 23. In some embodiments, in a cross-section (e.g., the YZ plane shown in FIG. 3F), the cured second molding layer 28 has an upper surface 280, a lower surface (not labeled), and second side surfaces 281. The upper surface 280 of the second molding layer 28 is connected to the second side surfaces 281 of the second molding layer 28, and the upper surface 280 of the second molding layer 28 and the second side surfaces 281 of the second molding layer 28 define second molding angles θ₄, θ₄′ (shown in FIG. 3F). The second molding angles θ₄, θ₄′ refer to angles formed between the upper surface 280 of the second molding layer 28 and the second side surfaces 281 at the two sides of the second molding layer 28, respectively. The second molding angles θ₄, θ₄′ may be different from each other but the second molding angles θ₄, θ₄′ are still greater than 90 degrees. In some embodiments, the second molding angle θ₄ (shown in FIG. 3F) is arranged corresponding to the second lid angle θ₂ (shown in FIG. 3F), while the second molding angle θ₄′ (shown in FIG. 3F) is arranged corresponding to the second lid angle θ₂′ (shown in FIG. 3F), so that the surface profiles of the two sides of the lid 23 (e.g., the surface profile of the second side surfaces 232 of the lid 23) can be matched with the surface profiles of the second molding side-surfaces 281. For example, the second lid angle θ₂ is equal to or slightly greater than the second molding angle θ₄, while the second lid angle θ₂′ is equal to or slightly greater than the second molding angle θ₄′. Accordingly, in FIG. 3F, when the lid 23 is further clamped on the second molding layer 28, the obtained surface profiles of the second side surfaces 281 of the second molding layer 28 may be substantially the same as the surface profiles of the lid 23 (e.g., the surface profiles of the second side surfaces 232 of the lid 23).

Please still refer to FIG. 3F. In some embodiments, the upper surface 280 of the cured second molding layer 28 is a horizontal plane and parallel to the upper surface 200 of the substrate 20. In some embodiments, the upper surface 280 of the cured second molding layer 28 is an inclined plane. For example, the thickness of the second molding layer 28 (i.e., the size along the Z direction in FIG. 3F) decreases in the direction away from the lid 23. In some embodiments, the upper surface 280 of the cured second molding layer 28 and the upper surface of the lid 23 are arranged as coplanar (as shown in FIG. 3F); for example, the second molding layer 28 and/or the lid 23 are thinned by chemical mechanical polishing until the upper surface of the lid 23 is exposed with the upper surface 280 of the second molding layer 28.

Please refer to FIG. 2. A plurality of solder balls 210 are arranged on the lower surface 204 of the substrate 20 so that the solder balls 210 are further arranged as the ball grid array 21. Each of the solder balls 210 may be electrically connected to at least one of the lower contacts 203 of the substrate 20. The material of the solder balls 210 may be various conductive metals, such as gold, silver, copper, tin or any combination thereof. The semiconductor packaging structure 2a shown in FIG. 2 can be generally formed at this stage.

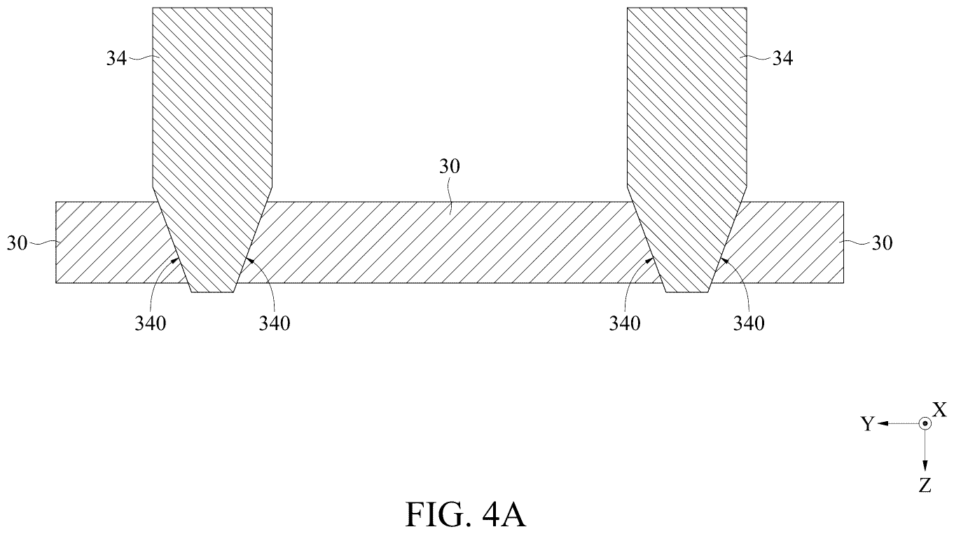

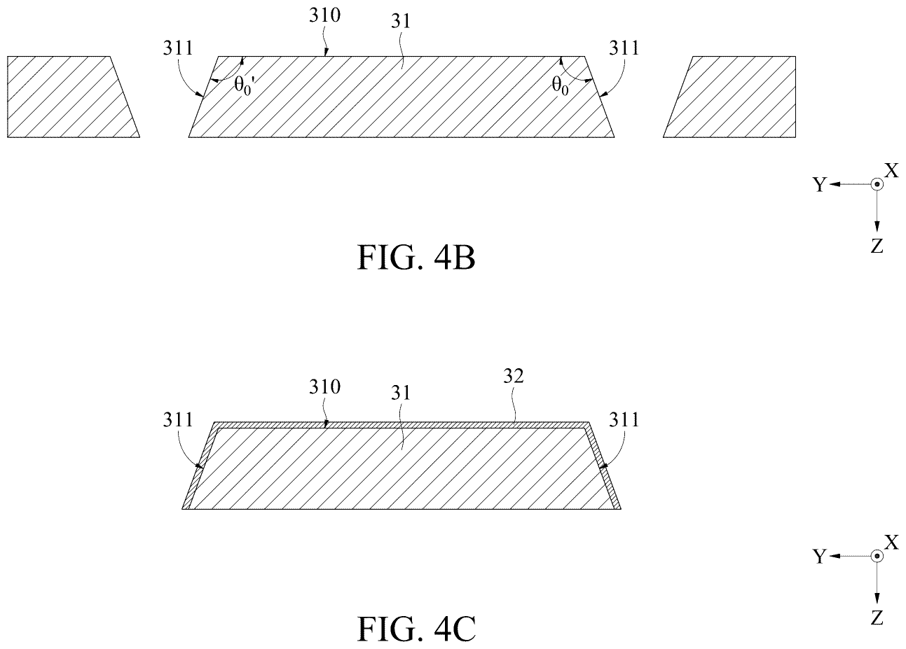

The manufacturing processes of the cover 31 are exemplarily described below through FIG. 4A to FIG. 4C.

Please refer to FIG. 4A and FIG. 4B. FIG. 4A is a schematic cross-sectional view of a semi-finished product of a cover 31 according to some embodiments; and FIG. 4B is a schematic cross-sectional view of a cover 31 according to some embodiments. First, a cover raw material 30 is provided. The material of the cover raw material 30 is the same as that of the cover 31 (shown in FIG. 3C); for example, the materials of both the cover raw material 30 and the cover 31 are glass with its transmittance to visible light greater than 90%. Next, at least one first cutter 34 is provided. In a cross-section (e.g., the YZ plane shown in FIG. 4A), the first cutter 34 has a lower surface (not labeled) and first cutter surfaces 340. The lower surface of the first cutter 34 is connected to the first cutter surfaces 340, and the lower surface of the first cutter 34 and the first cutter surfaces 340 define first cutter angles (not labeled), respectively. In some embodiments, each of the first cutter angles at the two sides of the first cutter 34 may be any degree identical to the corresponding one of the cover angles θ₀, θ₀′ at the two sides of the cover 31 (shown in FIG. 3C); for example, the first cutter angles at the two sides of the first cutter 34 are identical to the corresponding one of the cover angles θ₀, θ₀′, respectively. In some embodiments, the first cutter angles at the two sides of the first cutter 34 are identical to the corresponding first molding angles θ₃, θ₃′ of the first molding layer 27 (shown in FIG. 3D), respectively. At the same operation time, the cover raw material 30 may be cut by one or more first cutters 34 in a single-stage manner or in a multi-stage manner to form the cover 31 (shown in FIG. 4B). The single-stage manner refers to a process that the cover raw material 30 is cut only once to form the cover 31; for example, the cover raw material 30 is cut simultaneously with the first cutters 34 on the left and right sides of FIG. 4A to directly form the cover 31 shown in FIG. 4B. The multi-stage manner refers to a process that the cover raw material 30 is cut more than once to form the cover 31; for example, the cover raw material 30 is first cut by the first cutter 34 on the left side of FIG. 4A and then cut by the first cutter 34 on the right side of FIG. 4A to form the cover 31 shown in FIG. 4B.

Please refer to FIG. 4B. After the cover raw material 30 is cut, in a cross-section (e.g., the YZ plane shown in FIG. 4B), a cover 31 would be formed with a lower surface 310 and side surfaces 311 thereof. The lower surface 310 and the side surfaces 311 at the two sides of the cover 31 define the cover angles θ₀, θ₀′, respectively, and the two cover angles θ₀, θ₀′ may be identical to or different from each other. The specific embodiments of the cover 31 can be referred to the aforementioned specific embodiments, which is not further described in detail herein.

Please refer to FIG. 4C. FIG. 4C is schematic cross-sectional view of a cover 31 according to some embodiments. The first colloid 32 is further coated on the lower surface 310 of the cover 31 and the side surfaces 311 at the two sides of the cover 31, as shown in FIG. 4B. The material and the specific embodiments of the first colloid 32 can be referred to the aforementioned material and specific embodiments, which is not further described in detail herein. The cover 31 as shown in FIG. 3B and FIG. 3C as well as its first colloid 32 can be generally formed at this stage.

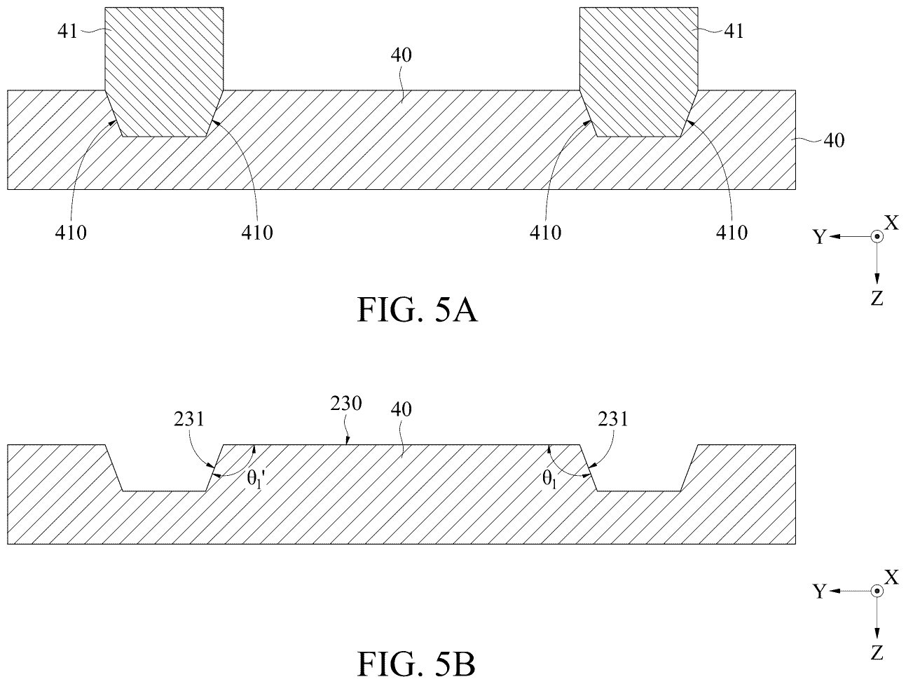

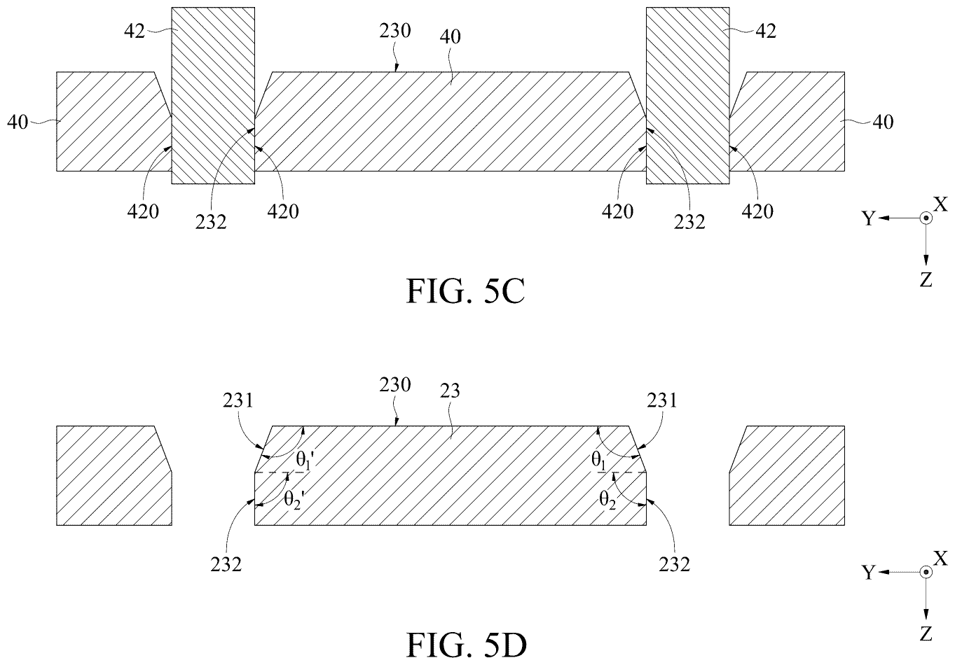

The manufacturing processes of the lid 23 are exemplarily described as below through FIG. 5A to FIG. 5D.

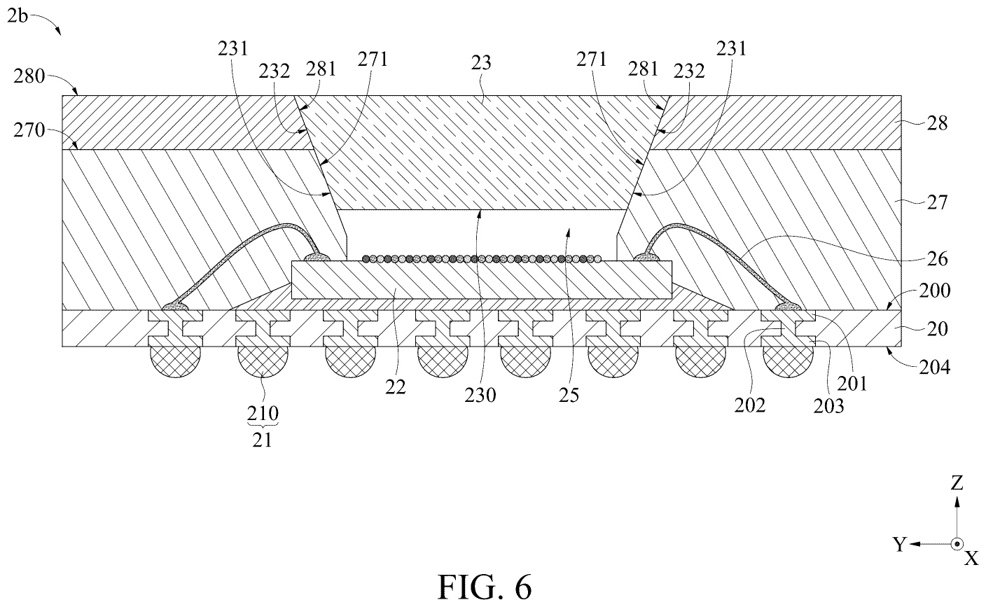

Please refer to FIG. 5A and FIG. 5B. FIG. 5A and FIG. 5B are schematic cross-sectional views of semi-finished products of a lid 23 according to some embodiments. First, a lid raw material 40 is provided. The material of the lid raw material 40 is the same as that of the lid 23 (shown in FIG. 3E); for example, the materials of both the lid raw material 40 and the lid 23 are glass with its transmittance to visible light greater than 90%. Next, at least one second cutter 41 is provided. In a cross-section (e.g., the YZ plane shown in FIG. 5A), the second cutter 41 has a lower surface (not labeled) and second cutter surfaces 410. The lower surface of the second cutter 41 is connected to the second cutter surfaces 410, and the lower surface of the second cutter 41 and the second cutter surfaces 410 define second cutter angles (not labeled), respectively. In some embodiments, each of the second cutter angles at the two sides of the second cutter 41 may be any degree identical to the corresponding one of the first lid angles θ₁, θ₁′ at the two sides of the lid 23 (shown in FIG. 3E); for example, the second cutter angles at the two sides of the second cutter 41 are identical to the corresponding first lid angles θ₁, θ₁′, respectively. In some embodiments, the second cutter angles at the two sides of the second cutter 41 are identical to the corresponding first molding angles θ₃, θ₃′ of the first molding layer 27 (shown in FIG. 3E), respectively. At the same operation time, the lid raw material 40 may be cut by one or more second cutters 41 in a single-stage manner or in a multi-stage manner to form the lid 23 (as shown in FIG. 6) or a semi-finished product thereof (as shown in FIG. 5B). The single-stage manner refers to a process that the lid raw material 40 is cut only once to form the lid 23 shown in FIG. 6 (which will be described in detail later) or a semi-finished product thereof as shown in FIG. 5B; for example, the lid raw material 40 is cut simultaneously with the second cutters 41 on the left and right sides of FIG. 5A to directly form the lid 23 shown in FIG. 6 or a semi-finished product thereof shown in FIG. 5B. The multi-stage manner refers to a process that the lid raw material 40 is cut more than once to form the lid 23 shown in FIG. 5D or FIG. 6 (which will be described in detail later); for example, the lid raw material 40 is first cut by the second cutter 41 on the left side of FIG. 5A and then cut by the second cutter 41 on the right side of FIG. 5A to form the lid 23 shown in FIG. 6 or a semi-finished product thereof shown in FIG. 5B.

Please refer to FIG. 5B. After the lid raw material 40 is cut by the second cutter(s) 41, a lid 23 or a semi-finished product thereof would be formed. For example, in a cross-section (e.g., the YZ plane shown in FIG. 5B), the semi-finished product of the lid 23 has a lower surface 230 and first side surfaces 231 thereof. The lower surface 230 and first side surfaces 231 at the two sides of the semi-finished product of the lid 23 define the first lid angles θ₁, θ₁′, respectively, and the two first lid angles θ₁, θ₁′ may be identical to or different from each other. The specific embodiments of the lid 23 and the semi-finished product thereof can be referred to the aforementioned specific embodiments, which is not further described in detail herein.

Please refer to FIG. 5C. FIG. 5C is a schematic cross-sectional view of a semi-finished product of a lid 23 according to some embodiments. At least one third cutter 42 is further provided. In a cross-section (e.g., the YZ plane shown in FIG. 5C), the third cutter 42 has a lower surface (not labeled) and third cutter surfaces 420 thereof. The lower surface of the third cutter 42 is connected to the third cutter surfaces 420, and the lower surface of the third cutter 42 and the third cutter surfaces 420 define third cutter angles (not labeled), respectively. In some embodiments, each of the third cutter angles at the two sides of the third cutter 42 may be any degree identical to the corresponding one of the second lid angles θ₂, θ₂′ at the two sides of the lid 23 (shown in FIG. 3F); for example, the second cutter angles at the two sides of the third cutter 42 are identical to the corresponding second lid angles θ₂, θ₂′, respectively. At the same operation time, the semi-finished product of the lid 23 may be cut by one or more third cutters 42 in a single-stage manner or in a multi-stage manner to form the lid 23 (shown in FIG. 5D or FIG. 6). The single-stage manner refers to a process that the semi-finished product of the lid 23 is cut only once to form the lid 23 shown in FIG. 5D or FIG. 6 (which will be described in detail later); for example, the semi-finished product of the lid 23 shown in FIG. 5B is cut simultaneously with the third cutters 42 on the left and right sides of FIG. 5C to directly form the lid 23 shown in FIG. 6. The multi-stage manner refers to a process that the semi-finished product of the lid 23 is cut more than once to form the lid 23 shown in FIG. 5D or FIG. 6 (which will be described in detail later); for example, the semi-finished product of the lid 23 shown in FIG. 5B is first cut by the third cutter 42 on the left side of FIG. 5C and then cut by the third cutter 42 on the right side of FIG. 5C to form the lid 23 shown in FIG. 5D or FIG. 6.

Please refer to FIG. 5D. FIG. 5D is a schematic cross-sectional view of a lid 23 according to some embodiments. After the semi-finished product of the lid 23 is cut by the third cutter(s) 42, in a cross-section (e.g., the YZ plane shown in FIG. 5D), the lid 23 would be formed with a lower surface 230, first side surfaces 231, and second side surfaces 232. The lower surface 230 of the lid 23 (e.g., a virtual plane or a virtual line parallel to the lower surface 230) and the second side surfaces 232 at the two sides of the lid 23 define the second lid angles θ₂, θ₂′, respectively, the two second lid angles θ₂, θ₂′ may be identical to or different from each other. The second lid angle θ₂ is less than or equal to the first lid angle θ₁, and the second lid angle θ₂′ is less than or equal to the first lid angle θ₁′. In some embodiments, as shown in FIG. 5C and FIG. 5D, the angles between the lower surface of the third cutter 42 and the third cutter surfaces 420 are respectively 90 degrees; therefore, after the lid 23 is cut by the third cutter(s) 42 (with two 90-degree angles formed at the two sides thereof), the second lid angles θ₂, θ₂′ at the two sides are also 90 degrees. The specific embodiments of the lid 23 can be referred to the aforementioned specific embodiments, which is not further described in detail herein. The lid 23 shown in FIG. 2 or FIG. 6 may be generally formed at this stage.

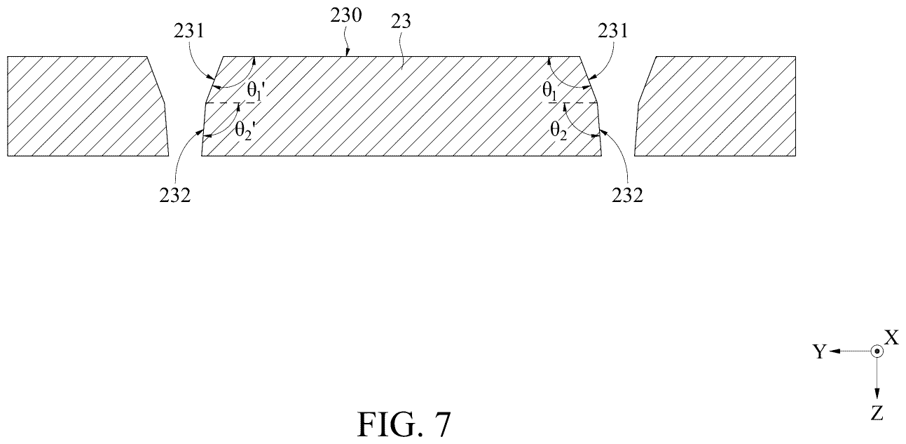

Please refer to FIG. 2, FIG. 6, and FIG. 7. FIG. 6 is a schematic cross-sectional view of a semiconductor packaging structure 2b according to a second embodiment; and FIG. 7 is a schematic cross-sectional view of a lid 23 according to some embodiments. The main difference between the semiconductor packaging structure 2a shown in FIG. 2 and the semiconductor packaging structure 2b shown in FIG. 6 is that, for example, the arrangements of angles between the first side surfaces 231 and the second side surfaces 232 of the lid 23. For example, the second lid angles θ₂, θ₂′ of the semiconductor packaging structure 2b may be greater than 90 degrees (shown in FIG. 7). For example, in FIG. 6 and FIG. 7, both the second lid angles θ₂, θ₂′ (shown in FIG. 7) are greater than 90 degrees, and the angles between the first side surfaces 231 and the second side surfaces 232 of the lid 23 are about 180 degrees; therefore, there is no significant step difference at the connections of the first lid side-surfaces 231 and the second lid side-surfaces 232 of the lid 23 (shown in FIG. 6). In some embodiments, as shown in FIG. 6, the first lid angle θ₁ is equal to the second lid angle θ₂ (and/or the first lid angle θ₁′ is equal to the second lid angle θ₂′) to form the side surfaces of the lid 23 without a significant step difference at the connections of the first side surfaces 231 and the second side surfaces 232. In other embodiments, as shown in FIG. 7, the first lid angle θ₁ is not equal to the second lid angle θ₂ (and/or the first lid angle θ₁′ is not equal to the second lid angle θ₂′) to form the side surfaces of the lid 23 with a significant step differences at the connections of the first side surfaces 231 and the second side surfaces 232; for example, in FIG. 7, the first lid angle θ₁ is greater than the second lid angle θ₂ (and/or the first lid angle θ₁′ is greater than the second lid angle θ₂′).

To sum up, in some embodiments, through setting a lid having at least one of its side-surfaces being inclined (e.g., the aforementioned first lid side-surface) and above the active surface of the image sensor chip as well as defining an air cavity by the lid, the active surface of the image sensor chip, and the molding layer (e.g., the aforementioned first molding layer), the light transmission path in the lid can be changed due to the reflection by the at least one inclined side-surface. Hence, the probability of the light transmitting to the air cavity can be reduced, thereby avoiding unnecessary interferences caused by light transmitting back and forth in the air cavity (e.g., flare phenomenon). In other words, a semiconductor packaging structure according to some embodiments can effectively solve the flare phenomenon known to the inventors. Meanwhile, in some embodiments, since there is no need to arrange spacers and/or a light shielding layer between the lid and the image sensor chip, not only the manufacturing time and costs for the arrangements of the spacers and/or the light shielding layer known to the inventors can be omitted, but also the unnecessary flare phenomenon can be avoided effectively.

Although the present disclosure is disclosed in the foregoing embodiments as above, it is not intended to limit the instant disclosure. Any person who is familiar with the relevant art can make some changes and modifications without departing from the spirit and scope of the present disclosure. Therefore, the scope of the present disclosure shall be subject to the definition of the scope of patent application attached to the specification.

What is claimed is:

1. A semiconductor packaging structure, comprising:
a substrate having an upper surface, a lower surface, and a trace between the upper surface and the lower surface, wherein the upper surface of the substrate has a plurality of upper contacts, the lower surface of the substrate has a plurality of lower contacts, and the upper contacts are electrically connected to the lower contacts through the trace;
an image sensor chip on the upper surface of the substrate;
a plurality of metal wires, wherein one end of each of the metal wires is electrically connected to the image sensor chip, and the other end of each of the metal wires is electrically connected to the upper contacts of the substrate;
a lid having a lower surface and a first side surface, wherein the lower surface of the lid is connected to the first side surface thereof, and a first lid angle between the lower surface of the lid and the first side surface of the lid is greater than 90 degrees;
a first molding layer laterally encapsulating the substrate, the metal wires, the image sensor chip, and the lid to expose a portion of the upper surface of the image sensor chip, and the first molding layer, the lower surface of the lid, and the exposed portion of an upper surface of the image sensor chip together define an air cavity; and
a ball grid array comprising a plurality of solder balls, wherein each of the solder balls is individually electrically connected to each of the lower contacts of the substrate.

2. The semiconductor packaging structure according to claim 1, wherein the lid further has a second side surface, the second side surface of the lid is connected to the first side surface of the lid, and a second lid angle between the lower surface of the lid and the second side surface of the lid is less than or equal to the first lid angle.

3. The semiconductor packaging structure according to claim 2, further comprising a second molding layer, the second molding layer is located on the first molding layer and laterally encapsulates the lid.

4. The semiconductor packaging structure according to claim 3, wherein the second molding layer laterally encapsulates the second side surface of the lid, and the first molding layer laterally encapsulates the first side surface of the lid.

5. The semiconductor packaging structure according to claim 1, wherein the lid further has a second side surface, the second side surface of the lid is connected to the first side surface of the lid, and a second lid angle between the lower surface of the lid and the second side surface of the lid is equal to 90 degrees.

6. The semiconductor packaging structure according to claim 5, further comprising a second molding layer, the second molding layer is located on the first molding layer and laterally encapsulates the lid.

7. The semiconductor packaging structure according to claim 6, wherein the second molding layer laterally encapsulates the second side surface of the lid, and the first molding layer laterally encapsulates the first side surface of the lid.

8. The semiconductor packaging structure according to claim 1, further comprising a second molding layer, the second molding layer is located on the first molding layer and laterally encapsulates the lid.

9. The semiconductor packaging structure according to claim 1, wherein the lid has two sides opposite to each other in a cross-sectional plane, each of the two sides has the first side surface of the lid, and the first lid angle between the lower surface of the lid and the first side surface of the lid at one side is different from the first lid angle between the lower surface of the lid and the first side surface of the lid at the other side.

10. The semiconductor packaging structure according to claim 1, wherein the lid has two sides opposite to each other in a cross-sectional plane, each of the two sides has the first side surface of the lid, and the first lid angle between the lower surface of the lid and the first side surface of the lid at one side is identical to the first lid angle between the lower surface of the lid and the first side surface of the lid at the other side.

11. The semiconductor packaging structure according to claim 10, wherein the lid at each of the two sides further has a second side surface in the cross-sectional plane, the second side surface of each of the two sides of the lid is connected to the first side surface of the lid corresponding to the each of the two sides, and a second lid angle between the lower surface of the lid and the second side surface of the lid at one side is different from a second lid angle between the lower surface of the lid and the second side surface of the lid at the other side.

12. The semiconductor packaging structure according to claim 10, wherein the lid at each of the two sides further has a second side surface in the cross-sectional plane, the second side surface of each of the two sides of the lid is connected to the first side surface of the lid corresponding to the each of the two sides, and a second lid angle between the lower surface of the lid and the second side surface of the lid at one side is identical to a second lid angle between the lower surface of the lid and the second side surface of the lid at the other side.

13. The semiconductor packaging structure according to claim 9, wherein the lid at each of the two sides further has a second side surface thereof in the cross-sectional plane, the second side surface of each of the two sides is connected to the first side surface of the lid corresponding to the each of the two sides, and a second lid angle between the lower surface of the lid and the second side surface of the lid at one side is different from a second lid angle between the lower surface of the lid and the second side surface of the lid at the other side.

14. The semiconductor packaging structure according to claim 9, wherein the lid at each of the two sides further has a second side surface in the cross-sectional plane, the second side surface of each of the two sides of the lid is connected to the first side surface of the lid corresponding to the each of the two sides, and a second lid angle between the lower surface of the lid and the second side surface of the lid at one side is identical to a second lid angle between the lower surface of the lid and the second side surface of the lid at the other side.
